(19) United States
(12) Patent Application Publication
(10) Pub. No.: US 2025/0175193 A1
(43) Pub. Date: May 29, 2025

(54) INFORMATION PROCESSING APPARATUS, INFORMATION PROCESSING METHOD, AND NON-TRANSITORY COMPUTER READABLE MEDIUM

(71) Applicant: Rakuten Group, Inc., Tokyo (JP)

(72) Inventors: Alameen NAJJAR, Tokyo (JP); Kyle MEDE, Tokyo (JP)

(73) Assignee: Rakuten Group, Inc., Tokyo (JP)

(21) Appl. No.: 18/954,770

(22) Filed: Nov. 21, 2024

(30) Foreign Application Priority Data
Nov. 27, 2023 (JP) 2023-199618

(51) Int. Cl. H03M 7/30

(52) U.S. Cl. CPC H03M 7/3064; H03M 7/3066; H03M 7/6011

(57) ABSTRACT

An information processing apparatus generates a plurality of character strings by encoding each of a plurality of pieces of continuous position data into a character string, the plurality of character strings each being a character string assigned to a region including a position specified by the respective piece of position data, groups the plurality of character strings into a plurality of groups of character strings, and divides each of the plurality of groups of character strings into a plurality of tokens.

### CROSS-REFERENCE TO RELATED APPLICATION(S)

This application claims priority to Japanese patent application No. 2023-199618, filed on Nov. 27, 2023; the entire contents of which are incorporated herein by reference.

### TECHNICAL FIELD

The present invention relates to a machine learning technology that uses trajectory data.

### BACKGROUND ART

In Natural Language Processing (NLP) technologies, a known machine learning model pre-trains using a large amount of data and, thereafter, relearns (fine-tunes) using supervised data so as to be able to adapt to downstream tasks (e.g., Patent Document 1). A machine learning model that goes through such a two-step learning process is also referred to as a foundation model.

In such a foundation model, pre-training is performed using general data that is not biased toward a specific task. Also, pre-training is typically performed using a large amount of unsupervised data. An example of a pre-training technique is MLM (Masked Language Modeling). MLM is a training technique that involves masking some of a plurality of tokens (units of text) included in an input statement (input data) and enabling the model to predict the masked tokens.

JP 2023-097204A is an example of related art.

### SUMMARY OF THE INVENTION

By performing pre-training and then fine-tuning directed to desired downstream tasks, a learning model adaptable to the downstream tasks can be realized, and, heretofore, learning models adapted to all manner of language tasks have been developed. Meanwhile, a learning model that is trained using trajectory data including position information that accompanies geographical movement by a user has yet to be specifically realized, despite growing interest. While position information acquired in a user device held by a user can be utilized as trajectory data of the user, the amount of data is enormous when collected from a large number of users, and it is important to use the trajectory data efficiently to train the learning model. To that end, tokens serving as training data need to be efficiently generated from the trajectory data.

The present invention has been made in view of the above problems and has an object to provide a technology for efficiently generating tokens serving as training data from trajectory data.

In order to solve the above problems, one aspect of an information processing apparatus includes: an encoding unit configured to generate a plurality of character strings by encoding each of a plurality of pieces of continuous position data into a character string, the plurality of character strings each being a character string assigned to a region including a position specified by the respective piece of position data; a grouping unit configured to group the plurality of character strings into a plurality of groups of character strings; and a tokenization unit configured to divide each of the plurality of groups of character strings into a plurality of tokens.

In order to solve the above problems, one aspect of an information processing method includes: generating a plurality of character strings by encoding each of a plurality of pieces of continuous position data into a character string, the plurality of character strings each being a character string assigned to a region including a position specified by the respective piece of position data; grouping the plurality of character strings into a plurality of groups of character strings; and dividing each of the plurality of groups of character strings into a plurality of tokens.

In order to solve the above problems, one aspect of an information processing program according to the present invention is a program for causing a computer to execute: encoding processing for generating a plurality of character strings by encoding each of a plurality of pieces of continuous position data into a character string, the plurality of character strings each being a character string assigned to a region including a position specified by the respective piece of position data; grouping processing for grouping the plurality of character strings into a plurality of groups of character strings; and tokenization processing for dividing each of the plurality of groups of character strings into a plurality of tokens.

According to the present invention, it becomes possible to efficiently generate tokens serving as training data from trajectory data.

A person skilled in the art will be able to understand the above-stated object, aspect, and advantages of the present invention, as well as other objects, aspects, and advantages of the present invention that are not mentioned above, from the following modes for carrying out the invention by referring to the accompanying drawings and claims.

### BRIEF DESCRIPTION OF THE DRAWINGS

FIG. 1 shows an example configuration of an information processing system according to an embodiment.

FIG. 2 shows an example functional configuration of an information processing apparatus according to the embodiment.

FIG. 3 shows a flowchart of tokenization processing.

FIG. 4A shows an example of a map on which a plurality of regions are arranged.

FIG. 4B is a diagram showing transformation of data from trajectory data into tokens.

FIG. 4C shows an example of tokens generated from hash values assigned to 49 hexagons.

FIG. 5 shows a flowchart of training processing.

FIG. 6 shows an example hardware configuration of the information processing apparatus according to the embodiment.

### EMBODIMENTS OF THE INVENTION

Embodiments of the present invention will now be described in detail with reference to the accompanying drawings. Out of the component elements described below, elements with the same functions have been assigned the same reference numerals, and description thereof is omitted. Note that the embodiments disclosed below are mere example implementations of the present invention, and it is possible to make changes and modifications as appropriate according to the configuration and/or various conditions of the apparatus to which the present invention is to be applied. Accordingly, the present invention is not limited to the embodiments described below. The combination of features described in these embodiments may include features that are not essential when implementing the present invention.

### Configuration of Information Processing System

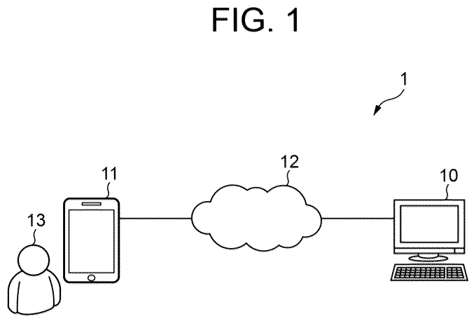

FIG. 1 shows an example configuration of an information processing system 1 according to the present embodiment. The information processing system 1 is constituted to include an information processing apparatus 10 and a user device 11. The information processing apparatus 10 and the user device 11 are configured to be capable of communicating with each other via a network 12. Apart from the Internet, the network 12 can include an intranet, a LAN (Local Area Network), a WAN (Wide Area Network), and a mobile communication network. Note that, in FIG. 1, one user device 11 is illustrated, but the information processing system 1 is configured to have a plurality of user devices, and, in the present disclosure, the plurality of user devices can be collectively referred to as the user device 11. Also, the user device 11 is operated by a user 13. In the present disclosure, the terms “user device” and “user” may be understood to be interchangeable.

The user device 11 is a mobile terminal that can be carried by the user 13. The user device 11 is, for example, a device such as a smartphone or a tablet, and is configured to be capable of communicating with the information processing apparatus 10 via the network 12. The user device 11 is provided with a positioning unit capable of acquiring position data (position information) of the user device 11. The positioning unit is, for example, a GPS (Global Positioning System) sensor. The user device 11 acquires a plurality of pieces of position data that are continuous along the movement of the user 13 and transmits the acquired position data to the information processing apparatus 10. Also, the user device 11 can transmit the position data to the information processing apparatus 10 with time information (timestamp) indicating the time at which the position data was acquired attached to the position data. The user device 11 can acquire position data at regular intervals or at predetermined times. The time for acquiring position data may also be instructed by another device. Note that the user device 11 may transmit position data with time information attached thereto to an external device other than the information processing apparatus 10 via the network 12.

The information processing apparatus 10 acquires the plurality of pieces of continuous position data received from the user device 11 as trajectory data. The information processing apparatus 10 then implements processing for training the learning model described later, using the trajectory data. The information processing apparatus 10 is able to acquire a large amount of different trajectory data from a large number of user devices including the user device 11. The information processing apparatus 10 similarly implements later-described processing on the various trajectory data in this case.

### Functional Configuration of Information Processing Apparatus

The information processing apparatus 10 according to the present embodiment is configured to acquire trajectory data including a plurality of pieces of position data and encode each of the plurality of pieces of position data included in the trajectory data into a character string to generate a plurality of character strings. Furthermore, the information processing apparatus 10 is configured to group (cluster) the plurality of character strings into a plurality of groups (clusters) of character strings, and to divide each of the plurality of groups of character strings into a plurality of tokens. Furthermore, the information processing apparatus 10 is configured to pre-train and fine-tune a language model serving as a machine learning model, using the plurality of tokens.

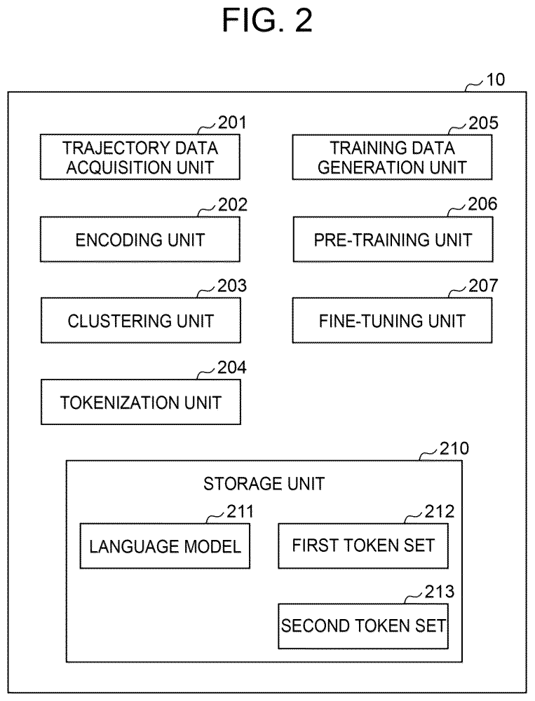

FIG. 2 shows an example of the functional configuration of the information processing apparatus 10 according to the present embodiment. As an example of the functional configuration, the information processing apparatus 10 has a trajectory data acquisition unit 201, an encoding unit 202, a clustering unit 203, a tokenization unit 204, a training data generation unit 205, a pre-training unit 206, a fine-tuning unit 207, and a storage unit 210. The storage unit 210 is configured to be capable of storing a language model (natural language processing model) 211, a first token set 212 which is an unsupervised training dataset, and a second token set 213 which is a supervised training dataset. Note that rather than the entire information processing apparatus 10 being provided in one apparatus, the information processing apparatus 10 may be divided between a plurality of apparatuses. For example, part of the information processing apparatus 10 may be provided in an external server device. In this case, the following functions are realized through cooperation between the information processing apparatus 10 and the external server device.

The trajectory data acquisition unit 201 acquires trajectory data that includes a plurality of pieces of continuous position data from each of the plurality of user devices including the user device 11. The encoding unit 202 encodes (converts) each of the plurality of pieces of position data included in the trajectory data acquired by the trajectory data acquisition unit 101 into a character string. The clustering unit 203 groups (clusters) the plurality of character strings obtained through encoding by the encoding unit 102 into a plurality of groups (clusters) of character strings. The tokenization unit 204 divides each of the plurality of groups of character strings grouped by the clustering unit 203 into a plurality of tokens. That is, the tokenization unit 204 generates a plurality of tokens. The training data generation unit 205 generates a first token set 212, which is an unsupervised training dataset, and a second token set 213, which is a supervised training dataset, from the plurality of tokens generated by the tokenization unit 204. The training data generation unit 205 stores the first token set 212 and the second token set 213 in the storage unit 210. The pre-training unit 206 pre-trains the language model 211, using the first token set 212. The fine-tuning unit 207 performs fine-tuning directed to a predetermined task on a pre-trained language model 211, using the second token set 213. Hereinafter, processing executed by the information processing apparatus 10 will be described, divided into tokenization processing and training processing.

### Tokenization Processing

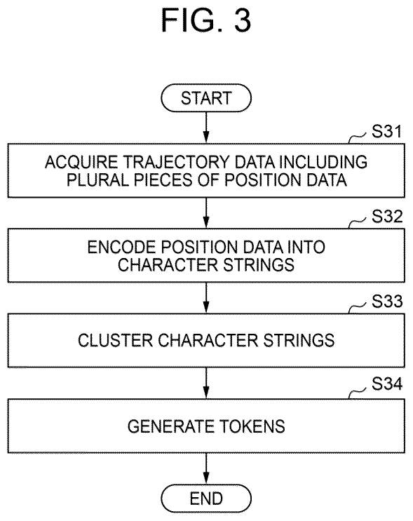

First, tokenization processing according to the present embodiment will be described. FIG. 3 shows a flowchart of tokenization processing executed by the information processing apparatus 10. The tokenization processing is started in a state where it is possible for the information processing unit 10 to acquire trajectory data including a plurality of pieces of continuous position data of the user device 11 (i.e., user 13) from the user device 11 via the network 12. Alternatively, the tokenization processing is started in a state where it is possible for the information processing apparatus 10 to acquire trajectory data of the user device 11 from an external device.

In step S31, the trajectory data acquisition unit 201 acquires trajectory data including a plurality of pieces of continuous position data. In the present embodiment, the position data is assumed to be data constituted by a latitude and a longitude. Alternatively, the position data may be data indicating a position specified by any coordinates on a map. In the present embodiment, the position data has time information (timestamp) indicating the time at which the position data was acquired by the user device 11 attached thereto.

In step S32, the encoding unit 202 encodes (converts) each of the plurality of pieces of position data included in the trajectory data acquired by the trajectory data acquisition unit 101 into a character string. Here, the character strings obtained through encoding may be any form of textual information. In the present embodiment, the encoding unit 102 uses a plurality of regions arranged in advance on a map. A character string is assigned to each of the plurality of regions, based on geographical location. The encoding unit 102 encodes each piece of position data into a character string assigned to a region that includes the position specified by the piece of position data. That is, the encoding unit 102 converts the pieces of continuous position data into discrete data (character strings), by mapping each piece of position data to one of the plurality of regions.

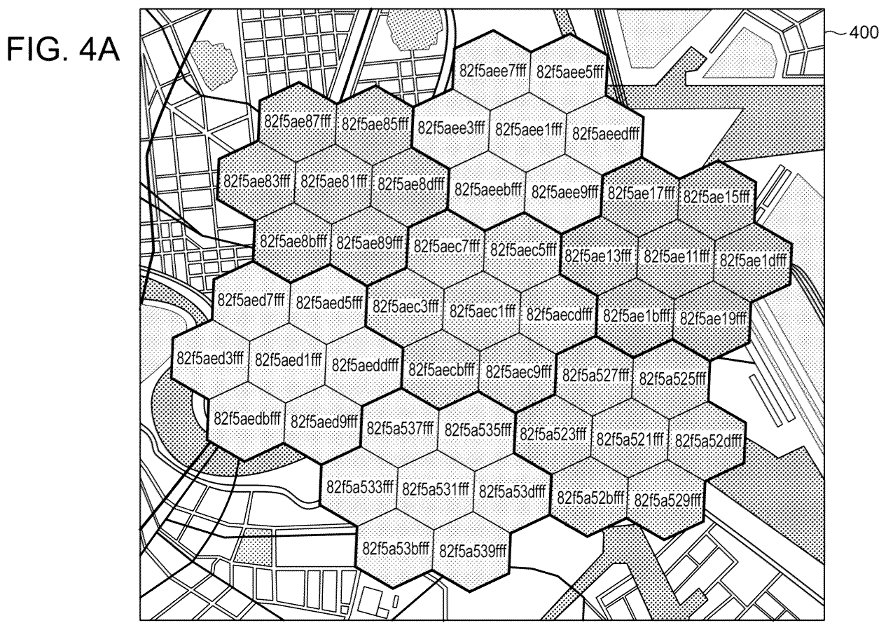

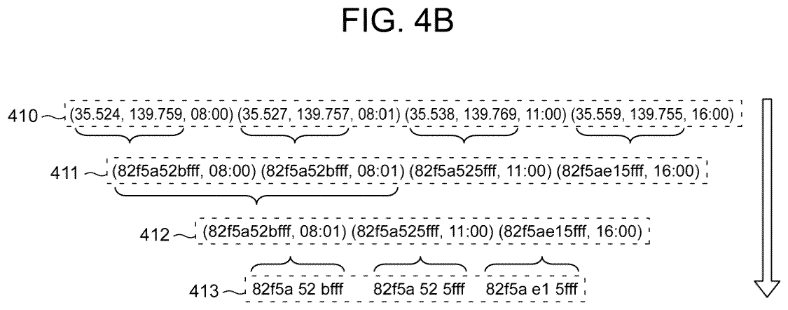

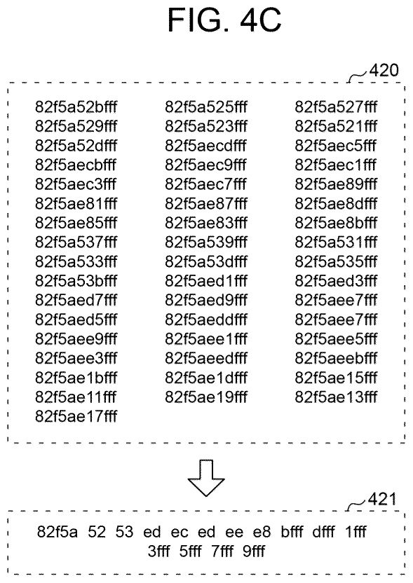

FIG. 4A shows an example of a map 400 on which a plurality of regions are arranged. The map 400 shows examples of a plurality of regions and character strings respectively assigned to the regions. In FIG. 4A, each region has a hexagonal shape as an example of a polygon. In the case of a hexagon, the quantization error that occurs when the user moves (error when converting position data to a character string) can be reduced. A hexagon also makes it possible to easily approximate the radius. Note that the regions need only touch but not overlap with adjacent regions, and the shape thereof is not limited to a hexagon. For example, the shape of the regions may be another polygon such as a pentagon.

In FIG. 4A, hash values (hash representations) corresponding to the geographical locations of the regions are shown as an example of the character strings respectively assigned to the regions (hexagons). In FIG. 4A, the hash value corresponding to each hexagon can be obtained by, for example, inputting the latitude and longitude of a predetermined position (e.g., center position) in the hexagon to a hash function as an argument (input value). The encoding unit 102 encodes (converts) the latitude and longitude indicated by the position data into a hash value corresponding to the region in which the latitude and longitude are located.

FIG. 4B is a diagram showing transformation of data from trajectory data into tokens. In FIG. 4B, trajectory data 410 is trajectory data (position data sequence) that includes four pieces of position data each constituted by a latitude and a longitude with time information attached thereto. The encoding unit 202 generates a hash value sequence 411, by converting each piece of position data of the trajectory data 410 into a hash value. The hash values in the hash value sequence 411 correspond to hash values assigned to the regions that include the positions specified by the position data, among the plurality of regions of the map 400 shown in FIG. 4A. In the hash value sequence 411, the position data (35.524, 139.759, 08:00) and (35.527, 139.757, 08:01) in the trajectory data 410 are converted into the same hash value (82f5a52bfff, 08:01) while maintaining the time information. This equates to the position of latitude=35.524 and longitude=139.759 and the position of latitude=35.527 and longitude=139.757 being located in the same region (same hexagon in the example in FIG. 4A) on the map. On the other hand, the position data (35.538, 139.769, 11:00) and (35.559, 139.755, 16:00) in the trajectory data 410 are converted into different hash values. This equates to the position of latitude=35.538 and longitude=139.769 and the position of latitude=35.559 and longitude=139.755 being located in different regions (different hexagons in the example in FIG. 4A) on the map.

In the present embodiment, each character string obtained through encoding by the encoding unit 102 is constituted by a plurality of blocks of characters corresponding to a plurality of hierarchical geographical areas (from large division areas to small division areas). Here, one or more common (i.e., the same) characters are used for common geographical areas. For example, character strings corresponding to the same numeric portions of the latitude and longitude are represented by one or more common characters, and constituted by a plurality of blocks as a result.

In the example in FIG. 4A, all 49 hexagons that are illustrated form the same large division (large-sized) area, and the characters “82f5a” are applied to this large division area. Therefore, the 49 hexagons are all prefixed with the characters “82f5a”. Also, groups of seven hexagons enclosed by bold lines each form the same medium division (middle-sized) area, and common characters are applied to each of the seven hexagons. That is, the characters “e8”, “ee”, “el”, “52”, “53”, “ed”, and “ec” are respectively applied following “82f5a”. Also, each of the seven hexagons forms a small division (small-sized) area, and different characters are applied to each of the hexagons. For example, the characters “7fff”, “5fff”, “dfff”, “9fff”, “bfff”, “3fff”, and “1fff” are respectively applied following “e8” to the seven hexagons in the medium division area to which “e8” is assigned. In this way, in the example in FIG. 4A, the hash value (character string) assigned to each region is constituted by at least three blocks.

Also, to give an example using addresses, assume the case where two addresses each corresponding to a position specified by a latitude and a longitude are “District 1, B Town, A City” and “District 2, B Town, A City”. In this case, the character strings corresponding to the two addresses are constituted such that the one or more characters representing “A City” and “B Town” are common, and the one or more characters representing “District 1” and “District 2” are different. Therefore, the character strings in this example are representations having a plurality of blocks that correspond to the plurality of geographical areas “district”, “town”, and “city”.

After encoding into character strings is performed, the clustering unit 203, in step S33, groups (clusters) the plurality of character strings obtained through encoding by the encoding unit 102 into a plurality of groups of character strings. Clustering removes excess (unnecessary) data. That is, noise is reduced. In the present embodiment, clustering is based on spatiotemporal proximity. Specifically, the clustering unit 203 performs clustering based on the similarity of the plurality of character strings obtained through encoding by the encoding unit 102 (i.e., proximity of positions specified by the position data) and the similarity of the time information attached to the character strings (i.e., proximity of times at which the position data is acquired). For example, the clustering unit 203 clusters, that is, merges, one or more character strings having a predetermined number of characters that match and time information that is within a predetermined time period, among the plurality of character strings, into one group. In the present embodiment, information indicating the predetermined number of characters and the predetermined time period (i.e., range of proximity of positions and times) may be set in advance in the information processing apparatus 10 or may be set by any program stored in a storage unit (ROM 602 or RAM 603 in FIG. 6). Alternatively, the clustering unit 203 may set or adjust information indicating the predetermined number of characters and the predetermined time period, in accordance with a predetermined instruction (e.g., instruction by operator).

An example of clustering will now be described, with reference to FIG. 4B. The clustering unit 203 determines the similarity of the plurality of hash values included in the hash value sequence 411 having time information attached thereto generated by the encoding unit 202. For example, the clustering unit 203 groups a plurality of hash values having the predetermined number of characters that match and time information that is within the predetermined time period, out of the plurality of character strings constituting the hash values, into one group. This equates to grouping a plurality of character strings obtained through encoding from a plurality of pieces of position data within a predetermined range and acquired within a predetermined time period into one group.

Assume that the clustering unit 203 determines that the time information attached to the first two hash values, out of (82f5a52bfff, 08:00), (82f5a52bfff, 08:01), (82f5a525fff, 11:00), and (82f5ae15fff, 16:00) included in the hash value sequence 411, is within the predetermined time period. The two hash values match. In this case, the clustering unit 203 groups the first two hash values into one group. That is, the first two hash values (82f5a52bfff, 08:00) and (82f5a52bfff, 08:01) are grouped into one group (82f5a52bfff, 08:01). Here, the most recent time information (=08:01), out of the time information attached to the hash values or position data, is attached as time information, but the present invention is not limited thereto. For example, the earliest time information or the average time information may also be employed. The clustering unit 203 then generates a clustered hash value sequence 412. If there are no clustered hash values, the hash value sequences generated by the encoding unit 202 and the clustering unit 203 will be the same.

By performing clustering, a plurality of character strings (in the present embodiment, a plurality of hash values) obtained through encoding from a plurality of pieces of position data are organized into one or more groups (clusters) based on spatiotemporal proximity. Noise in the data is thereby suppressed and the density of trajectory points is controlled. The density of the trajectory points can be controlled by adjusting conditions relating to spatiotemporal proximity (range of proximity of positions and times).

In step S34, the tokenization unit 204 generates a plurality of tokens by tokenizing (dividing) the plurality of groups of character strings clustered by the clustering unit 203. As aforementioned, each character string is constituted by a plurality of hierarchical blocks, and the tokenization unit 204 utilizes the plurality of blocks to generate the plurality of tokens. For example, the tokenization unit 204 generates the plurality of tokens by dividing each of the plurality of groups of character strings clustered by the clustering unit 203 into a plurality of hierarchical blocks. Each block equates to one token. In the present embodiment, the character strings are hash values, and the tokenization unit 204 divides each hash value into a plurality of sub-hash values and generates each sub-hash value as a token.

An example of tokenization will now be described, with reference to FIG. 4B. The tokenization unit 204 divides each of the plurality of hash values included in the hash value sequence 412 into a plurality of tokens (sub-hash values) and generates a token sequence 413 consisting of a plurality of tokens. The token sequence 413 includes a plurality of the same tokens (e.g., “52”), but the tokens are respectively generated from different clustered hash values and are thus treated as different tokens (data).

In such a procedure, a plurality of tokens are generated from trajectory data.

Performing encoding and clustering processing on trajectory data enables a plurality of tokens to be generated from the trajectory data, so as to represent the features of the trajectory (i.e., such that the features of the trajectory are extracted). Also, a plurality of tokens can be generated with a reduced data amount of the trajectory data. In the example in FIG. 4B, the token sequence 413 representing the features of the trajectory is generated from the trajectory data 410 having time information attached thereto. As is also clear from FIG. 4B, the data amount of the token sequence 413 is significantly reduced from the data amount of the trajectory data 410.

The reduction of the data amount through tokenization will be further described, with reference to FIG. 4C. FIG. 4C shows an example of tokens generated from hash values assigned to the 49 hexagons shown in FIG. 4A. In FIG. 4C, a hash value group 420 includes 49 hash values respectively assigned to the 49 hexagons shown in FIG. 4A. A token group 421 is a set of tokens generated from the hash value group 420 in accordance with the procedure described above. As can be seen from FIG. 4C, the data amount of the token group 421 is greatly reduced from the data amount of the hash value group 420. Therefore, in the case where trajectory data is obtained from a large number of users via user devices, for example, a large-scale dataset including a large number of tokens representing the features of trajectories can be generated from the trajectory data.

In this way, the information processing apparatus 10 converts a plurality of pieces of position data into a plurality of character strings based on the positions specified by the position data, and groups the plurality of character strings into a plurality of clusters, based on the proximity (similarity) of the character strings and the proximity (similarity) of the time information indicating the time at which the position data was acquired. The information processing apparatus 10 then divides the character strings included in the plurality of clusters into a plurality of tokens. As a result of such processing, the trajectory data including the plurality of pieces of position data is converted into tokens obtained by features of the trajectories being extracted after noise has been reduced. When trajectory data is obtained from a large number of users, a large-scale dataset including a large number of tokens indicating the features of the trajectories can thereby be generated from the trajectory data. Such a large-scale dataset is used in order to train the language model 211.

### Training Processing

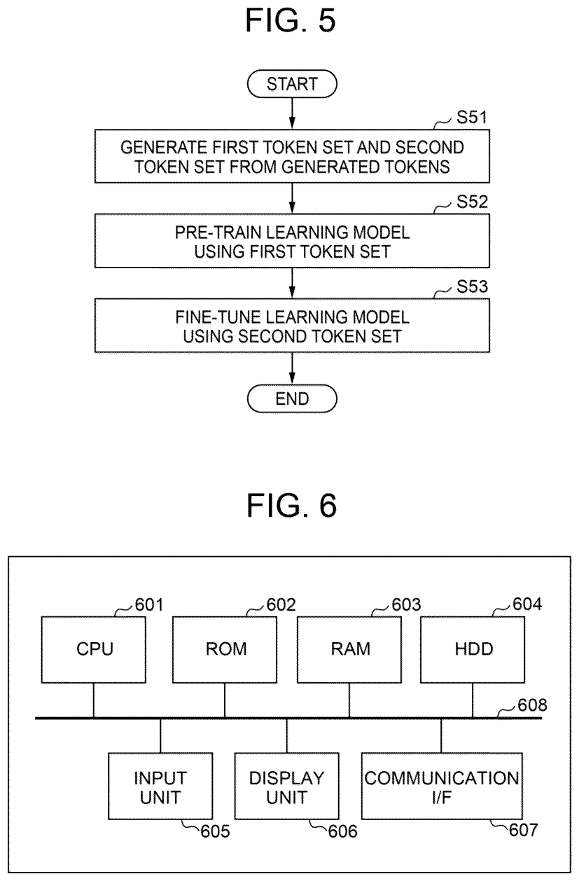

Next, training processing according to the present embodiment will be described. FIG. 5 shows a flowchart of the training processing executed by the information processing apparatus 10. The tokens generated by the tokenization unit 204 are used in the training processing. First, in step S51, the training data generation unit 205 generates a first token set and a second token set from the plurality of tokens generated by the tokenization unit 204.

The training data generation unit 205 generates, as the first token set 212, an unsupervised training dataset from the plurality of tokens generated by the tokenization unit 204 and stores the generated dataset in the storage unit 210. That is, the first token set 212 is a training dataset that is not dependent on any task. In the present embodiment, in order to pre-train the language model 211 with the MLM (Masked Language Modeling) technique, the training data generation unit 205 generates, as the first token set 212, a plurality of sets of tokens obtained by masking some of the plurality of tokens generated from one piece of trajectory data. The first token set 212 is used for pre-training by the pre-training unit 206.

Also, the training data generation unit 205 generates, as the second token set 213, a supervised training dataset from the plurality of tokens generated by the tokenization unit 204 and stores the generated dataset in the storage unit 210. The second token set is constituted to include a plurality of sets in which a label (ground truth data) for a targeted task is attached to the plurality of tokens generated from one piece of trajectory data. The second token set 213 is used in fine-tuning performed by the fine-tuning unit 207. Targeted tasks can be tasks for location-based services relating to urban planning, transportation, and the like.

In step S52, the pre-training unit 206 pre-trains the language model 211, using the first token set (unsupervised training dataset). The language model 211 is, for example, a machine learning model that incorporates an architecture called a transformer. That is, the language model 211 is a language model that is based on a transformer. A known transformer is BERT (Bidirectional Encoder Representation from Transformers). Some of the tokens included in the first token set 212 are masked, and the pre-training unit 206 trains the language model 211 by inferring the masked tokens. The language model 211 is trained with a method that is task-independent and enables an extensive understanding of the trajectory data to be obtained. In the present embodiment, given that it is possible to pre-train the language model 211 from a large-scale dataset of tokens generated from trajectory data, the language model 211 can be referred to as an LTM (Large Trajectory Model) on the basis of LLMs (Large Language Models).

In step S53, the fine-tuning unit 207 performs fine-tuning of the pre-trained language model 211, using a second token set (supervised training dataset) generated for a targeted task. Parameters (weights) of the pre-trained language model 211 are adjusted, so as to be able to understand the plurality of tokens generated from the trajectory data. Fine-tuning is training that provides the pre-trained language model 211 with a clear task. Through fine-tuning, the parameters of the language model 211 are adjusted so as to optimize the performance of the model in performing the targeted task, resulting in a language model 211 that is adapted to the task.

In this way, in the present embodiment, trajectory data constituted by position data of a user obtained by a user device is utilized as the trajectory data of the user. Such trajectory data can be obtained from a large number of users and is factual real-world information that can be useful training data. In the present embodiment, a large amount of trajectory data obtained from a large number of users is converted into a plurality of tokens representing the features of trajectories after having reduced noise and reduced the data amount by the procedure described above. Since the data amount of the plurality of tokens is greatly reduced from the trajectory data, the language model 211 can be efficiently trained using the plurality of tokens, even when using a large amount of trajectory data.

Note that, in the above embodiment, an example is described in which character strings obtained through encoding are constituted by a plurality of blocks that correspond to hierarchical geographical areas and tokenization is performed utilizing the plurality of blocks, but the nature of the plurality of blocks is not limited thereto. For example, character strings obtained through encoding may be constituted by a plurality of blocks set on a map that are based on predetermined rules and may be tokenized utilizing the plurality of blocks.

### Hardware Configuration of Information Processing Unit

Next, an example hardware configuration of the information processing apparatus 10 will be described. FIG. 6 is a block diagram showing an example of the hardware configuration of the information processing apparatus 10 according to the present embodiment.

The information processing apparatus 10 according to the present embodiment can be implemented on one or a plurality of any computer, mobile device, or any other processing platform.

Referring to FIG. 6, an example is shown in which the information processing apparatus 10 is implemented on a single computer, but the information processing apparatus 10 according to the present embodiment may be implemented on a computer system that includes a plurality of computers. The plurality of computers may be connected to each other communicatively by a wired or wireless network.

As shown in FIG. 6, the information processing unit 10 may be provided with a CPU (Central Processing Unit) 601, a ROM (Read Only Memory) 602, a RAM (Random Access Memory) 603, an HDD (Hard Disk Drive) 604, an input unit 605, a display unit 606, a communication I/F (communication unit) (interface) 607, and a system bus 608. The information processing apparatus 10 may also be provided with an external memory.

The CPU 601 functions to perform overall control of the operations of the information processing apparatus 10, and controls the constituent units (602 to 607) via the system bus 608, which is a data transmission path.

The ROM 602 is a non-volatile memory that stores control programs and the like necessary in order for the CPU 601 to execute processing. The programs include instructions (code) for causing processing according to the above embodiment to be executed. Note that the programs may also be stored in a non-volatile memory such as the HDD 604 or an SSD (Solid State Drive) or in an external memory such as a removable storage medium (not shown).

The RAM 603 is a volatile memory and functions as a main memory, a work area, and the like of the CPU 601. That is, the CPU 601 realizes various functional operations by loading necessary programs and the like into the RAM 603 from the ROM 602 when executing processing and executing the loaded programs and the like. The RAM 603 can include the storage unit 210 shown in FIG. 2.

The HDD 604 stores various data, information and the like necessary when the CPU 601 performs processing using programs, for example. Also, various data, information, and the like obtained by the CPU 601 performing processing using programs and the like, for example, are stored in the HDD 604.

The input unit 605 is constituted by a keyboard, a pointing device such as a mouse, or the like.

The display unit 606 is constituted by a monitor such as a liquid crystal display (LCD). The display unit 606 may function as a GUI (Graphical User Interface), by being constituted in combination with the input unit 605.

The communication I/F 607 is an interface that controls communication between the information processing apparatus 10 and external devices. The communication I/F 607 provides an interface with a network and executes communication with external devices via the network. Various data, parameters, and the like are transmitted to and received from external devices via the communication I/F 607. In the present embodiment, the communication I/F 607 may execute communication via a wired LAN (Local Area Network) or a leased line conforming to a communication standard such as Ethernet (registered trademark). The network that is usable in the present embodiment is, however, not limited thereto and may be constituted by a wireless network. This wireless network includes wireless PANs (Personal Area Networks) such as Bluetooth (registered trademark), ZigBee (registered trademark), and UWB (Ultra Wide Band). Also included are wireless LANs (Local Area Networks) such as Wi-Fi (Wireless Fidelity) (registered trademark) and wireless MANs (Metropolitan Area Networks) such as WiMAX (registered trademark). Wireless WANs (Wide Area Networks) such as 4G and 5G are further included. Note that as long as the network communicatively connects devices to each other and communication is possible, the standard, scale, and configuration of communication are not limited to the above.

At least some of the functions of the elements of the information processing apparatus 10 shown in FIG. 2 can be realized by the CPU 601 executing programs. At least some of the functions of the elements of the information processing apparatus 10 shown in FIG. 2 may, however, be operated as dedicated hardware. In this case, the dedicated hardware operates under the control of the CPU 601. The disclosure includes the following embodiments.

[1] An information processing apparatus comprising: an encoding unit configured to generate a plurality of character strings by encoding each of a plurality of pieces of continuous position data into a character string, the plurality of character strings each being a character string assigned to a region including a position specified by the respective piece of position data; a grouping unit configured to group the plurality of character strings into a plurality of groups of character strings; and a tokenization unit configured to divide each of the plurality of groups of character strings into a plurality of tokens.

[2] The information processing apparatus according to [1], wherein the plurality of pieces of position data are each constituted by a latitude and a longitude.

[3] The information processing apparatus according to [1] or [2], wherein the region is one of a plurality of regions arranged in advance on a map.

[4] The information processing apparatus according to any one of [1] to [3], wherein the encoding unit generates the plurality of character strings by attaching time information indicating a time at which each of the plurality of pieces of position data is acquired to the respective piece of position data, and the grouping unit groups the plurality of character strings into the plurality of groups of character strings, based on a similarity of the character strings and a similarity of the time information.

[5] The information processing apparatus according to any one of [1] to [4], wherein the plurality of character strings generated by the encoding unit are each constituted by a plurality of blocks, and the tokenization unit divides each of the plurality of groups of character strings into the plurality of tokens, utilizing the plurality of blocks.

[6] The information processing apparatus according to any one of [1] to [5], wherein the plurality of character strings are each a hash representation based on the respective piece of position data.

[7] The information processing apparatus according to any one of [1] to [6], further comprising: a first token set generation unit configured to generate, from the plurality of tokens, a first token set in which one or more of the tokens are masked; and a pre-training unit configured to pre-train a language model that is based on a transformer, using the first token set.

The information processing apparatus according to [7], further comprising: a second token set generation unit configured to generate, from the plurality of tokens, a second token set in which a label for a predetermined task is attached to each token; and a fine-tuning unit configured to fine-tuning the pre-trained language model, using the second token set.

What is claimed is:

1. An information processing apparatus comprising:
an encoding unit configured to generate a plurality of character strings by encoding each of a plurality of pieces of continuous position data into a character string, the plurality of character strings each being a character string assigned to a region including a position specified by the respective piece of position data;
a grouping unit configured to group the plurality of character strings into a plurality of groups of character strings; and
a tokenization unit configured to divide each of the plurality of groups of character strings into a plurality of tokens.

2. The information processing apparatus according to claim 1,
wherein the plurality of pieces of position data are each constituted by a latitude and a longitude.

3. The information processing apparatus according to claim 1,
wherein the region is one of a plurality of regions arranged in advance on a map.

4. The information processing apparatus according to claim 1,
wherein the encoding unit generates the plurality of character strings by attaching time information indicating a time at which each of the plurality of pieces of position data is acquired to the respective piece of position data, and
the grouping unit groups the plurality of character strings into the plurality of groups of character strings, based on a similarity of the character strings and a similarity of the time information.

5. The information processing apparatus according to claim 1,
wherein the plurality of character strings generated by the encoding unit are each constituted by a plurality of blocks, and
the tokenization unit divides each of the plurality of groups of character strings into the plurality of tokens, utilizing the plurality of blocks.

6. The information processing apparatus according to claim 1,
wherein the plurality of character strings are each a hash representation based on the respective piece of position data.

7. The information processing apparatus according to claim 1, further comprising:
a first token set generation unit configured to generate, from the plurality of tokens, a first token set in which one or more of the tokens are masked; and
a pre-training unit configured to pre-train a language model that is based on a transformer, using the first token set.

8. The information processing apparatus according to claim 7, further comprising:
a second token set generation unit configured to generate, from the plurality of tokens, a second token set in which a label for a predetermined task is attached to each token; and
a fine-tuning unit configured to fine-tuning the pre-trained language model, using the second token set.

9. An information processing method comprising:
generating a plurality of character strings by encoding each of a plurality of pieces of continuous position data into a character string, the plurality of character strings each being a character string assigned to a region including a position specified by the respective piece of position data;
grouping the plurality of character strings into a plurality of groups of character strings; and
dividing each of the plurality of groups of character strings into a plurality of tokens.

10. A non-transitory computer readable medium storing an information processing program for causing a computer to execute:
encoding processing for generating a plurality of character strings by encoding each of a plurality of pieces of continuous position data into a character string, the plurality of character strings each being a character string assigned to a region including a position specified by the respective piece of position data;
grouping processing for grouping the plurality of character strings into a plurality of groups of character strings; and
tokenization processing for dividing each of the plurality of groups of character strings into a plurality of tokens.
